(19) United States
(12) Patent Application Publication
(10) Pub. No.: US 2025/0318317 A1
(43) Pub. Date: Oct. 9, 2025

(54) MANUFACTURING METHOD AND CONDUCTIVE PASTE FOR SOLAR CELL

(71) Applicant: INDUSTRIAL TECHNOLOGY RESEARCH INSTITUTE, Hsinchu (TW)

(72) Inventors: Chih-Jeng HUANG, Tainan City (TW); Chun-Ping LIN, Tainan City (TW); Han-Chen CHANG, Tainan City (TW)

(73) Assignee: INDUSTRIAL TECHNOLOGY RESEARCH INSTITUTE, Hsinchu (TW)

(21) Appl. No.: 18/937,678

(22) Filed: Nov. 5, 2024

Related U.S. Application Data
(60) Provisional application No. 63/573,631, filed on Apr. 3, 2024.

(30) Foreign Application Priority Data
Sep. 2, 2024 (TW) 113133070

(51) Int. Cl. H01L 31/0224; H01B 1/22; H01L 31/18

(52) U.S. Cl. CPC H10F 77/254; H10F 71/121; H10F 77/211; H10F 77/251; H01B 1/22

(57) ABSTRACT

A manufacturing method for a solar cell includes the following steps. The manufacturing method includes providing a solar cell semi-finished product. The manufacturing method includes performing a laser opening process to form openings. The manufacturing method includes forming a conductive paste in the openings. The manufacturing method includes performing a firing process. The manufacturing method includes performing a laser-enhanced contact optimization process. The openings expose the semiconductor doping layer of the solar cell semi-finished product. The conductive paste includes 80 to 120 parts by weight of core-shell particles, 0.1 to 14 parts by weight of glass frit, 5 to 25 parts by weight of adhesive resin, and 5 to 30 parts by weight of solvent. Each of the core-shell particles includes a core and a shell layer, and the core includes copper.

### CROSS REFERENCE TO RELATED APPLICATIONS

This application claims the benefit of U.S. Provisional Application No. 63/573,631, filed Apr. 3, 2024, and Taiwan Patent Application No. 113133070, filed on Sep. 2, 2024, the entirety of which is incorporated by reference herein.

### BACKGROUND OF THE INVENTION

### Field of the Invention

The present invention relates to a manufacturing method and a conductive paste for a cell, and, in particular, to a manufacturing method and a conductive paste for a solar cell.

### Description of the Related Art

Solar energy is an inexhaustible and environmentally friendly source of energy. A solar cell is a photovoltaic element that converts the light energy of sunlight directly into electricity. In solar cell manufacturing processes, a silver paste is currently used to form the electrodes in the solar cells. However, this silver paste is expensive, so it is expected to be replaced by a cheaper conductive paste.

A tunnel oxide passivated contact (TOPCon) solar cell is a type of solar cell based on the principle of selective carrier transport technology. The TOPCon solar cell is one of the most competitive high-efficiency solar cells on the market. The TOPCon solar cell can effectively reduce the rate of carrier recombination on the back side of the cell, improve the conversion efficiency of the solar cell, and maintain good stability even in a high-temperature environment.

Currently, TOPCon solar cells are manufactured by etching through a passivation layer and forming metal ohmic contacts using a paste containing glass frit in a high-temperature process. However, a copper paste cannot be used in the preparation of TOPCon solar cells because it oxidises rapidly at high temperatures and has high contact resistance.

### BRIEF SUMMARY OF THE INVENTION

An embodiment of the present invention provides a manufacturing method for a solar cell. The manufacturing method for the solar cell includes the following steps. Providing a solar cell semi-finished product; performing a laser opening process to form an opening; forming a conductive paste in the opening; performing a firing process, and performing a laser-enhanced contact optimization process. The solar cell semi-finished product includes a silicon substrate, a first passivation layer disposed on the silicon substrate, a semiconductor doping layer disposed between the silicon substrate and the first passivation layer, and an oxide layer disposed between the silicon substrate and the semiconductor doping layer. The openings expose the semiconductor doping layer of the solar cell semi-finished product. The conductive paste includes 80 to 120 parts by weight of a plurality of core-shell particles, 0.1 to 14 parts by weight of a glass frit, 5 to 25 parts by weight of an adhesive resin, and 5 to 30 parts by weight of a solvent. Each of the core-shell particles includes a core and a shell layer, and the core includes copper.

An embodiment of the present invention provides a conductive paste. The conductive paste includes 80 to 120 parts by weight of a plurality of core-shell particles, 0.1 to 14 parts by weight of a glass frit, 5 to 25 parts by weight of an adhesive resin, and 5 to 30 parts by weight of a solvent, wherein each of the core-shell particles includes a core and a shell layer, and the core includes copper.

### BRIEF DESCRIPTION OF THE DRAWINGS

The present invention can be more fully understood by reading the subsequent detailed description and examples with references made to the accompanying drawings, wherein:

FIG. 1 is a flowchart of a manufacturing method for a solar cell according to an embodiment of the present disclosure; and

FIGS. 2A to 2E are partial schematic views of a solar cell semi-finished product during the preparation of the solar cell according to an embodiment of the present disclosure.

### DETAILED DESCRIPTION OF THE INVENTION

The following is a detailed description of some embodiments of the present disclosure. It should be understood that the following description provides many different embodiments or examples for implementing different embodiments of the present disclosure. The particular components and arrangements described below are intended only to briefly and clearly describe some embodiments of the present disclosure. These are intended to be examples only and not limitations of the present disclosure. In addition, the present disclosure may repeat reference numerals and/or letters in the various examples. This repetition is for the purpose of simplicity and clarity and does not in itself dictate a relationship between the various embodiments and/or configurations discussed.

Here, the terms “about”, “approximately”, “substantially” usually means within 20%, within 10%, within 5%, within 3%, within 2%, within 1% or within 0.5% of a given value or range. Here, the given value is an approximate number. That is, in the absence of a specific description of “about”, “approximately”, “substantially”, the meaning of “about”, “approximately”, “substantially” may still be implied.

Here, the term “less than or equal to” indicates a range that contains a given value and values below that given value, and the term “greater than or equal to” indicates a range that contains a given value and values above that given value. Conversely, the term “less than” indicates a range that contains values less than a given value but does not contain that given value, and the term “greater than” indicates a range that contains values more than a given value but does not contain that given value. For example, “greater than or equal to a” means a range including values of a and values above a, and “greater than a” means a range including values more than a but not including a. Here, the term “between c and d” is used to include c, d, and any values between c and d.

In the present disclosure, the term “any combination thereof” is used to indicate combinations of two or more of the listed elements. For example, “any combination thereof” in “including A, B, C, or any combinations thereof” indicates combinations including at least one of AB, AC, BC, and ABC.

Unless defined otherwise, all technical and scientific terms used herein have the same meaning as commonly understood by one of ordinary skills in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

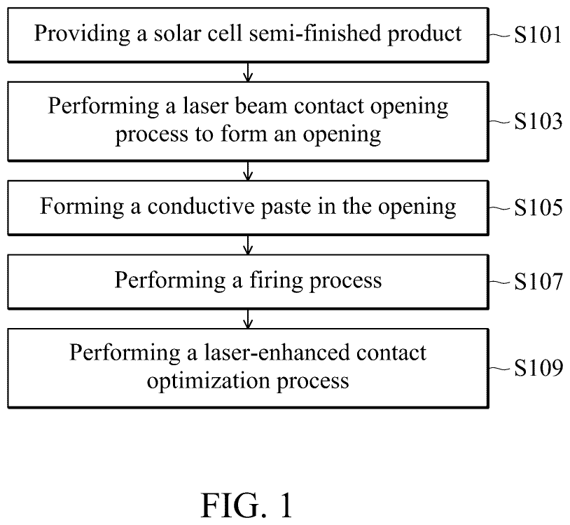

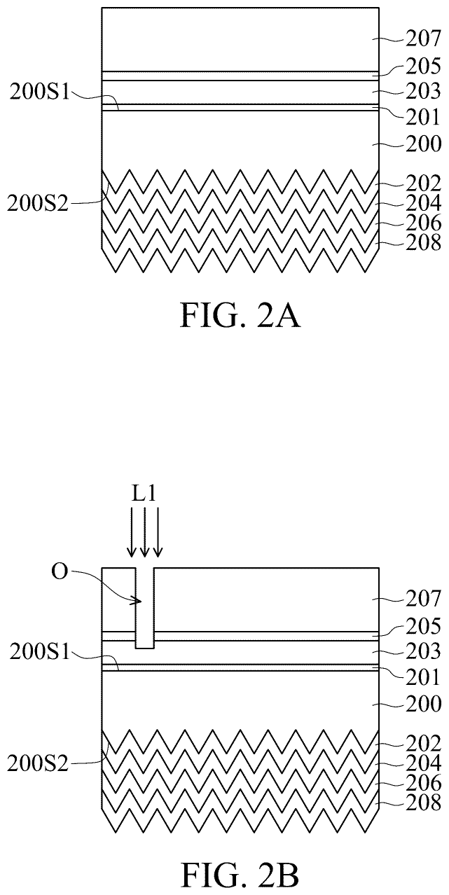

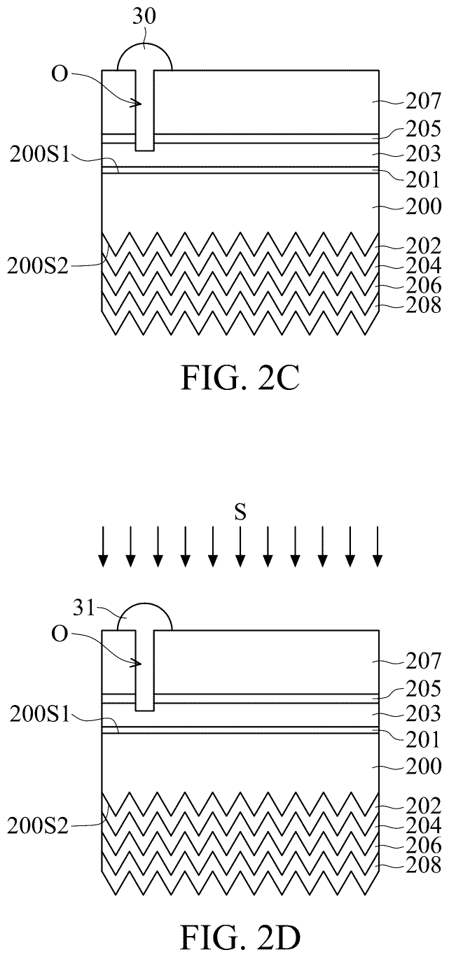

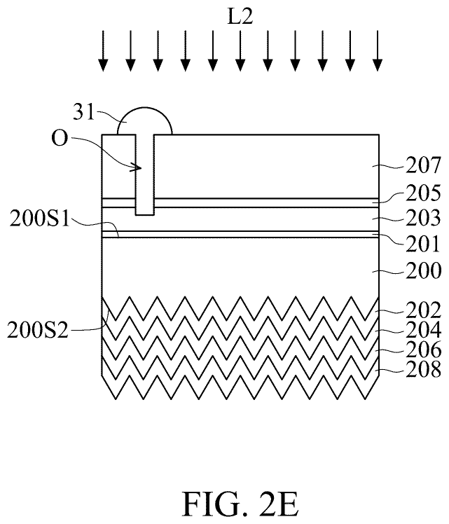

FIG. 1 is a flowchart of a manufacturing method for a solar cell according to an embodiment of the present disclosure. FIGS. 2A to 2E are partial schematic views of a solar cell semi-finished product during the preparation of the solar cell according to an embodiment of the present disclosure. The manufacturing method for a solar cell of the present disclosure is further described hereinafter with reference to FIG. 1 and FIGS. 2A to 2E.

As shown in FIG. 1, the manufacturing method for the solar cell of the present disclosure includes: a step S101 of providing a solar cell semi-finished product; a step S103 of performing a laser opening process to form an opening; a step S105 of forming a conductive paste in the opening; a step S107 of performing a firing process; and a step S109 of performing a laser-enhanced contact optimization process.

As shown in FIG. 2A, the solar cell semi-finished product provided in the step S101 includes a silicon substrate 200, a first passivation layer 207 disposed on the silicon substrate 200, a first semiconductor doping layer 203 disposed between the silicon substrate 200 and the first passivation layer 207, and a first oxide layer 201 disposed between the silicon substrate 200 and the first semiconductor doping layer 203. The silicon substrate 200 has a first surface 200S1 and a second surface 200S2 opposite the first surface 200S1. In some embodiments, the first passivation layer 207, the first semiconductor doping layer 203, and the first oxide layer 201 may be disposed on the first surface 200S1 of the silicon substrate 200. In some embodiments, the solar cell semi-finished product provided in the step S101 may further include a second passivation layer 205 disposed between the first passivation layer 207 and the first semiconductor doping layer 203. In some embodiments, the solar cell semi-finished product provided in the step S101 may further include a third passivation layer 208, a second semiconductor doping layer 204, and a second oxide layer 202 disposed on the second surface 200S2 of the silicon substrate 200, as shown in FIG. 2A. In this embodiment, the silicon substrate 200 is disposed between the first oxide layer 201 and the second oxide layer 202, the second oxide layer 202 is disposed between the silicon substrate 200 and the third passivation layer 208, and the second semiconductor doping layer 204 is disposed between the second oxide layer 202 and the third passivation layer 208. In some embodiments, the solar cell semi-finished product provided in the step S101 may further include a fourth passivation layer 206 disposed between the third passivation layer 208 and the second semiconductor doping layer 204, as shown in FIG. 2A, but the present disclosure is not limited thereto.

In some embodiments, the step S101 may include steps of providing a silicon substrate; depositing a first multilayer structure; and depositing a second multilayer structure, wherein the first multilayer structure and the second multilayer structure are disposed on two sides of the silicon substrate, but the present disclosure is not limited thereto. In some embodiments, the step S101 may not include the step of depositing the second multilayer structure. The first multilayer structure may include a first oxide layer 201, a first semiconductor doping layer 203, and a first passivation layer 207. In some embodiments, the first multilayer structure may further include a second passivation layer 205, but the present disclosure is not limited thereto. The second multilayer structure may include a second oxide layer 202, a second semiconductor doping layer 204, and a third passivation layer 208. In some embodiments, the second multilayer structure may further include a fourth passivation layer 206, but the present disclosure is not limited thereto.

The step of providing the silicon substrate may further include a substrate cleaning process and/or a texture structure forming process. The substrate cleaning process may include cleaning the silicon substrate 200 with a cleaning solution. The cleaning solution may include a sulfuric acid, a hydrochloric acid, an ammonium hydroxide, a hydrogen peroxide, a hydrogen fluoride, a deionized water, or any combination thereof, but the present disclosure is not limited thereto. The texture structure forming process may include forming a texture structure including a plurality of protrusions and depressions on the surface of the silicon substrate 200 using a potassium hydroxide, a deionized water, a flocking additive, or any combination thereof. In some embodiments, in the texture structure forming process, the texture structure includes a plurality of protrusions and depressions formed on the second surface 200S2 of the silicon substrate 200, as shown in FIG. 2A, but the present disclosure is not limited thereto. In some embodiments, the texture structure includes a plurality of protrusions and depressions formed on the first surface 200S1 of the silicon substrate 200 in the texture structure forming process.

The step of depositing the first multilayer structure may be performed after the step of providing the silicon substrate. In the step of depositing the first multilayer structure, the first oxide layer 201, the first semiconductor doping layer 203, the optional second passivation layer 205, and the first passivation layer 207 may be sequentially deposited on the first surface 200S1 of the silicon substrate 200. In the step of depositing the first multilayer structure, the first oxide layer 201, the first semiconductor doping layer 203, the optional second passivation layer 205, and the first passivation layer 207 may be deposited on the first surface 200S1 of the silicon substrate 200 by a physical deposition process, a chemical deposition process, or a combination thereof. Examples of the physical deposition process may include a vacuum evaporation, a sputtering deposition, an ion deposition, and the like, but the present disclosure is not limited thereto. Examples of the chemical deposition processes may include an electroplating, a chemical vapor deposition, a low-pressure chemical vapor deposition (LPCVD), a plasma-enhanced chemical vapor deposition (PECVD), and the like, but the present disclosure is not limited thereto.

The step of depositing the second multilayer structure may be performed before, after, or simultaneously with the step of depositing the first multilayer structure. In the step of depositing the second multilayer structure, the second oxide layer 202, the second semiconductor doping layer 204, the optional fourth passivation layer 206, and the third passivation layer 208 may be deposited sequentially on the second surface 200S2 of the silicon substrate 200. In the step of depositing the second multilayer structure, the second oxide layer 202, the second semiconductor doping layer 204, the optional fourth passivation layer 206, and the third passivation layer 208 may be deposited on the second surface 200S2 of the silicon substrate 200 by a physical deposition process, a chemical deposition process, or a combination thereof. Examples of the physical deposition process and the chemical deposition process are described above and will not be repeated herein.

In some embodiments, the first oxide layer 201 and the second oxide layer 202 may include a tunneling oxide layer. The first oxide layer 201 and the second oxide layer 202 may include the same or different materials. In some embodiments, the first oxide layer 201 and the second oxide layer 202 may include a silicon oxide.

In some embodiments, the first semiconductor doping layer 203 and the second semiconductor doping layer 204 may include a doping silicon layer. The doping silicon layer may include an amorphous silicon, a microcrystalline silicon, a polycrystalline silicon, a monocrystalline silicon, a silicon carbide, or any combination thereof, but the present disclosure is not limited thereto. In some embodiments, one of the first semiconductor doping layer 203 and the second semiconductor doping layer 204 may include P-type ions, and the other may include N-type ions. Examples of the P-type ions may include, but are not limited to, boron ions, aluminum ions, gallium ions, platinum ions, or any combination of thereof. Examples of the N-type ions may include, but are not limited to, phosphorus ions, arsenic ions, single paper ions, bismuth ions, or any combination thereof.

In some embodiments, the second passivation layer 205 and the fourth passivation layer 206 may include an aluminum nitride, a silicon oxide, or a combination thereof. In some embodiments, the first passivation layer 207 and the third passivation layer 208 may include a silicon nitride, a silicon oxynitride, a silicon oxide, an aluminum oxide, or any combination thereof, but the present disclosure is not limited thereto. The first passivation layer 207 and the third passivation layer 208 may include the same or different materials. In some embodiments, the first passivation layer 207 and the third passivation layer 208 may include a silicon nitride.

The laser opening process of the step S103 includes forming an opening O in the solar cell semi-finished product using a first laser L1. In some embodiments, the first laser L1 may include a pico second (ps) laser or a femto second (fs) laser having a laser wavelength of 300 nm to 500 nm. In some embodiments, the laser opening process may perform on the first passivation layer 207 of the solar cell semi-finished product. The laser opening process may form an opening O exposing the first semiconductor doping layer 203. The opening O may extend into the first semiconductor doping layer 203 but does not penetrate the first semiconductor doping layer 203. In some embodiments, the solar cell semi-finished product resulting from the step S103 may include a structure such as shown in FIG. 2B, but the present disclosure is not limited thereto. In some embodiments, the laser opening process may perform on the third passivation layer 208 of the solar cell semi-finished product. The laser opening process may form an opening exposing the second semiconductor doping layer 204. The opening may extend into the second semiconductor doping layer 204 but not through the second semiconductor doping layer 204. In the following, an embodiment in which the step S103 includes performing a laser opening process on the first passivation layer 207 and the solar cell semi-finished product obtained after the step S103 has a structure as shown in FIG. 2B is used as an example to illustrate the present disclosure.

A conductive paste 30 is formed in the opening O in the step S105. The conductive paste 30 used in the step S105 may include 80 to 120 parts by weight of a plurality of core-shell particles, 0.1 to 14 parts by weight of a glass frit, 5 to 25 parts by weight of an adhesive resin, and 5 to 30 parts by weight of a solvent. Each of the core-shell particle includes a core and a shell layer, and the core includes copper. In some embodiments, the conductive paste may include 90 to 110 parts by weight of the core-shell particles, 0.15 to 12 parts by weight of the glass frit, 5 to 25 parts by weight of the adhesive resin, and 5 to 30 parts by weight of the solvent. In some embodiments, the conductive paste may include 100 parts by weight of the core-shell particles, 0.2 to 8 parts by weight of the glass frit, 5 to 25 parts by weight of the adhesive resin, and 5 to 30 parts by weight of the solvent. Each of the core-shell particles in the conductive paste 30 includes a copper-containing core and a shell layer encompassing the core. The shell layer may include a conductive material that is less susceptible to oxidation at high temperatures than copper. For example, in some embodiments, the shell layer may include a metal less active than copper, such as a precious metal including gold, silver, platinum, and/or alloys thereof, but the present disclosure is not limited thereto. In some embodiments, the shell layer may include nickel or an alloy thereof. In some embodiments, the shell layer may be a single-layer structure or a multi-layer structure including a plurality of layers. In embodiments in which the shell layer includes a single layer structure, the shell layer may include a single layer of a conductive material. In some embodiments, the shell layer may be a single layer structure including silver, nickel, or an alloy thereof, but the present disclosure is not limited thereto. In embodiments in which the shell layer includes a multi-layer structure, the plurality of layers in the multi-layer structure may include the same or different conductive materials. In some embodiments, the shell layer may be a multilayer structure including silver, nickel, or alloys thereof, but the present disclosure is not limited thereto. For example, the shell layer may be a multilayer structure including a single layer of silver and a single layer of nickel, but the present disclosure is not limited thereto. In some embodiments, the core-shell particle includes a structure including, in an order from the inside to the outside, a copper core, a single layer of silver, and a single layer of nickel, or a copper core, a single layer of nickel, and a single layer of silver.

In some embodiments, based on a total weight of 100 wt % of the core-shell particle, the core may be 20 wt % to 70 wt % and the shell layer may be 80 wt % to 30 wt %. That is, in some embodiments, the weight ratio of the shell layer to the core in the core-shell particle may be 80:20 to 30:70. In some embodiments, the core may be 30 wt % to 60 wt %, and the shell layer maybe 70 wt % to 40 wt %. In some embodiments, the core may be 50 wt % and the shell layer may be 50 wt %. In embodiments in which the shell layer is 80 wt % to 20 wt %, the shell layer of the core-shell particle can completely encapsulate the core to reduce a risk of oxidization of the core and to have a lower cost of producing an electrode having good electrical properties. In embodiments in which the shell layer content in the core-shell particle is high, the cost reduction is not obvious. In embodiments in which the shell layer content in the core-shell particle is low, the core will not be effectively encapsulated and a resistance of the electrode will be poor.

The glass frit in the conductive paste 30 may include a lead oxide (PbOₓ), a silicon oxide (SiO₂), a boron trioxide (B₂O₃), an aluminum oxide (Al₂O₃), a zirconium oxide (ZrO₂), a zinc oxide (ZnO), a bismuth oxide (Bi₂O₃), a strontium oxide (SrO), a titanium oxide (TiO₂), a platinum oxide (La₂O₃), a vanadium oxide (V₂O₅), a chalcogenide (GeO₂), or any combination thereof, but the present disclosure is not limited thereto. In some embodiments, the glass frit may include a lead oxide. In some embodiments, the weight ratio of the core-shell particles to the glass frit in the conductive paste 30 may be 80 to 120:0.1 to 14. In some embodiments, based on 100 parts by weight of the core-shell particles in the conductive paste, the conductive paste may include 0.1 to 14 parts by weight, 0.15 to 12 parts by weight, 0.18 to 10 parts by weight, or 0.2 to 8 parts by weight of the glass frit. If the conductive paste includes too much glass frit, the glass frit may etch through layers under the electrode during a high-temperature process in an electrode manufacturing process. If the conductive paste includes too little glass frit, it results in high resistance and is unable to lower a sintering temperature. A conductive paste 30 having a weight ratio of the core-shell particles to the glass frit within the above range will produce an electrode having good electrical characteristics.

The adhesive resin may include any base material. In some embodiments, the adhesive resin may include any base material that can be vaporized during a high-temperature process (in which the temperature is above 700° C., 500° C., or 400° C.). In some embodiments, examples of the adhesive resins may include, but are not limited to, a polymer resin, a hydroxyethyl cellulose, an ethyl cellulose, a polyvinyl butyral resin, an epoxy resin, an acrylic resin, a phenolic resin, a urea melamine resin, or any combination thereof. Examples of the polymer resin may include, but are not limited to, a polystyrene-poly(ethylene-propylene)-polystyrene (SEPS) resin, a polystyrene-poly(ethylene-butylene)-polystyrene (SEBS) resin, a polystyrene (PS) resin, or any combination thereof. In some embodiments, the adhesive resin may include a polystyrene-poly(ethylene-propylene)-polystyrene resin. In some embodiments, based on 100 parts by weight of the core-shell particles in the conductive paste, the conductive paste may include 5 to 25 parts by weight, 8 to 20 parts by weight, 10 to 15 parts by weight, or 12 parts by weight of the adhesive resin.

The solvent may include any compound capable of dissolving the core-shell particles, the glass frit, and the adhesive resin. In some embodiments, the solvent may include an ester compound, an ether compound, an alcohol compound, or any combination thereof. In some embodiments, examples of the solvents may include, but are not limited to, 2,2,4-Trimethyl-1,3-pentanediol monoisobutyrate, diethylene glycol butyl ether acetate, ethylene glycol butyl ether phthalate, diethylene glycol butyl ether, pentaerythritol triacrylate, terpineol, dihydroterpineol, ethylene glycol phenyl ether, propylene glycol phenyl ether, diethylene glycol monobutyl ether, diethylene glycol butylether acetate, diethylene glycol monoethyl ether, diethylene glycol monobutyl ether, dihydrotepinyl acetate, diethylene glycol monoethyl ether acetate, diethylene glycol monobutyl ether acetate, or any combination thereof. In some embodiments, the solvent may include diethylene glycol butyl ether acetate. In some embodiments, based on 100 parts by weight of the core-shell particles in the conductive paste, the conductive paste may include 5 to 30 parts by weight, 8 to 25 parts by weight, 10 to 20 parts by weight, or 15 parts by weight of the solvent.

In some embodiments, the step S105 may include forming the conductive paste 30 in the opening O using a screen printing process, a physical vapor deposition process, an ink jet printing process, and any combination thereof. In some embodiments, the solar cell semi-finished product obtained after the step S105 may have a structure as shown in FIG. 2C.

A sintering process S of the step S107 is performed after the step S105. In some embodiments, the sintering process S of the step S107 is performed on the solar cell semi-finished product having a structure as shown in FIG. 2C. The conductive paste 30 in FIG. 2C may be formed an electrode 31 by the sintering process S of the step S107, as shown in FIG. 2D. In some embodiments, after the step S107, the solar cell semi-finished product may have a structure as shown in FIG. 2D. The sintering process S may include using a sintering temperature that is greater than a glass transition temperature (Tg) of the glass frit in the conductive paste 30. In some embodiments, the sintering temperature may be 300° C. to 650° C., 350° C. to 600° C., 375° C. to 550° C., 400° C. to 500° C., or 425° C. to 450° C. When the sintering temperature (e.g., 300° C.) in the sintering process S is greater than the glass transition temperature of the glass frit in the conductive paste 30, the solar cell produced by the manufacturing method for the solar cell of the present disclosure will have good electrical characteristics and low manufacturing costs. If the sintering temperature in the sintering process S is too high, the electrical characteristics of the solar cell produced by the manufacturing method for the solar cell of the present disclosure may be poor due to oxidization of the core-shell particles in the conductive paste 30. If the sintering temperature in the sintering process S is too low, the contact resistance of the resulting electrode is high. The term “sintering temperature” herein refers to an average temperature measured on the silicon substrate 200 of the solar cell semi-finished product during the sintering process S. In some embodiments, the sintering process S may include sintering using a sintering furnace. In this embodiment, a temperature of the sintering furnace will be about 100° C. higher than the sintering temperature.

The laser-enhanced contact optimization process of the step S109 is performed after the step S107. In some embodiments, the laser-enhanced contact optimization process of the step S109 is performed on a solar cell semi-finished product having the structure as shown in FIG. 2D. The laser-enhanced contact optimization process may be performed on an entire finished solar cell product obtained after sintering of the solar cell electrode as shown in FIG. 2E, but the present disclosure is not limited thereto. In some embodiments, the laser-enhanced contact optimization process may be performed on a localized area of the finished solar cell product. In some embodiments, the laser-enhanced contact optimization process may include irradiating all or a portion of the finished solar cell product having a structure as shown in FIG. 2D by a second laser L2 while applying a bias voltage. In some embodiments, the second laser L2 may be irradiated in a direction from the first passivation layer 207 toward the silicon substrate 200 as shown in FIG. 2E, but the present disclosure is not limited thereto. In some embodiments, the second laser L2 may irradiate in a direction from the silicon substrate 200 toward the first passivation layer 207. In some embodiments, the second laser L2 may include a laser wavelength of 400 nm to 1500 nm and may have a laser spot area greater than 10⁴ μm². In some embodiments, the laser-enhanced contact optimization process may include using a second laser L2 having a laser wavelength of 400 nm to 1500 nm, a bias voltage of −30V to 30V, and a performing temperature of 20° C. to 300° C. In some embodiments, the second laser L2 may have a laser wavelength of 800 nm to 1200 nm or 1000 nm to 1150 nm. In some embodiments, the bias voltage may be −25V to 25V or −22V to 15V. In some embodiments, the performing temperature may be 150° C. to 300° C. or 180° C. to 250° C. The laser-enhanced contact optimization process may significantly reduce a contact resistance between the metal (e.g., electrode 31) and the semiconductor (e.g., the first semiconductor doping layer 203) in the solar cell semi-finished product.

In an embodiment in which the laser opening process is performed on the third passivation layer 208 of the solar cell semi-finished product and forms an opening exposing the second semiconductor doping layer 204, the steps S105 and S107 described above may be performed to form an electrode in the opening to form a solar cell. The step S109 may be performed after the electrode is formed in the opening. In some embodiments, the step S109 may be performed after the electrode is formed in the opening and after the electrode 31 is formed.

A manufacturing method for a solar cell using a conductive paste including a glass frit together with a laser opening process can obtain a solar cell having a good contact resistance (Rs) and a low manufacturing cost.

An embodiment of the present invention provides a conductive paste as mentioned above.

One or more advantages of the present disclosure will be further illustrated by reference to the following examples. However, these examples are intended only to illustrate embodiments of the present disclosure and are not intended to limit the scope of the embodiments of the present disclosure.

### Preparation of Conductive Paste

Mixing ingredients according to the ingredients and proportions listed in Table 1 and Table 2 to obtain Slurries 1 to 7, Slurry A, and Slurry B. The term “pbw” in Table 1 and Table 2 indicates parts by weight.

TABLE 1

| | Slurry 1 | Slurry 2 | Slurry 3 | Slurry 4 | Slurry 5 |
|---|---|---|---|---|---|
| Silver-coated copper core-shell particles | 100 | 100 | 100 | 100 | 0 |
| (pbw) | | | | | |
| Silver-coated nickel-coated copper core- | 0 | 0 | 0 | 0 | 100 |
| shell particles (pbw) | | | | | |
| Lead oxide (pbw) | 3 | 0.2 | 8 | 15 | 3 |
| SEPS resin (pbw) | 12 | 12 | 12 | 12 | 12 |
| Diethylene glycol monobutyl ether | 15 | 15 | 15 | 15 | 15 |
| acetate (pbw) | | | | | |
| Silver content in core-shell particle | 50% | 50% | 50% | 50% | 40%* |
| (wt %) | | | | | |
| Copper core content in core-shell | 50% | 50% | 50% | 50% | 50% |
| particle (wt %) | | | | | |

*in Slurry 5, silver content in the core-shell particle is 40 wt %, and nickel content in the core-shell particle is 10 wt %

TABLE 2

| | Slurry 6 | Slurry 7 | Slurry A | Slurry B |
|---|---|---|---|---|
| Silver-coated copper core-shell particles | 0 | 0 | 0 | 100 |
| (pbw) | | | | |
| Nickel-coated silver-coated copper core- | 100 | 0 | 0 | 0 |
| shell particles (pbw) | | | | |
| Nickel-coated copper core-shell particles | 0 | 100 | 0 | 0 |
| (pbw) | | | | |
| Silver particles (pbw) | 0 | 0 | 100 | 0 |
| Lead oxide (pbw) | 3 | 3 | 3 | 0 |
| SEPS resin (pbw) | 12 | 12 | 12 | 12 |
| Diethylene glycol monobutyl ether acetate | 15 | 15 | 15 | 15 |
| (pbw) | | | | |
| Silver content in core-shell particle (wt %) | 40%* | 0% | 100% | 50% |
| Copper core content in core-shell particle | 50% | 50% | 0% | 50% |
| (wt %) | | | | |

*in Slurry6, silver content in core-shell particle is 40 wt %, and nickel content in core-shell particle is 10 wt %

### Preparation of Solar Cells

### Preparation of Solar Cell of Example 1

Slurry A was printed on a solar cell semi-finished product and sintered at a sintering temperature of 680° C. to obtain the solar cell of Example 1.

### Preparation of Solar Cell of Example 2

Slurry A was printed on a solar cell semi-finished product and sintered at a sintering temperature of 640° C. to obtain the solar cell of Example 2.

### Preparation of Solar Cell of Example 3

Slurry A was printed on a solar cell semi-finished product and sintered at a sintering temperature of 640° C. The sintered solar cell semi-finished product was subjected to a laser-enhanced contact optimization process using a second laser (1064 nm nano laser, power of 50 W, scanning speed of 50 M/s, laser spot diameter of 200 μm), a bias voltage of −20V, and a performing temperature of 200° C. to obtain the solar cell of Example 3.

### Preparation of Solar Cell of Examples 4, 6, 8, 10, 12, 14, 16, 18, 20, 24, 26, 28, 30, 32, and 34

A first laser (355 nm UV pico laser, power of 8 W, scanning speed of 25 M/s) was used to form an opening in the solar cell semi-finished products. Slurries 1 to 7 and Slurry B were printed into the opening instead of Slurry A as shown in Table 3 and were sintered at a sintering temperature shown in Table 3 to obtain the solar cells of Examples 4, 6, 8, 10, 12, 14, 16, 18, 20, 24, 26, 28, 30, 32, and 34.

### Preparation of Solar Cell of Examples 5, 7, 9, 11, 13, 15, 17, 19, 21, 25, 27, 29, 31, 33, and 35

A first laser (355 nm UV pico laser, power of 8 W, scanning speed of 25 M/s) was used to form an opening in the solar cell semi-finished products. Slurries 1 to 7 and Slurry B were printed into the opening instead of Slurry A as shown in Table 3 and were sintered at a sintering temperature shown in Table 3. The sintered solar cell semi-finished products were subjected to a laser-enhanced contact optimization process using a second laser (1064 nm nano laser, power of 50 W, scanning speed of 50 M/s, laser spot diameter of 200 μm), a bias voltage of −20V, and a performing temperature of 200° C. to obtain the solar cells of Examples 5, 7, 9, 11, 13, 15, 17, 19, 21, 25, 27, 29, 31, 33, and 35.

### Preparation of Solar Cell of Example 22

The solar cell of Example 22 was prepared in substantially the same manner as that of Example 1 except that Slurry 1 was used instead of Slurry A and was sintered at a sintering temperature of 400° C.

### Preparation of Solar Cell of Example 23

Slurry 1 was printed on a solar cell semi-finished product and sintered at a sintering temperature of 400° C. The sintered solar cell semi-finished product was subjected to a laser-enhanced contact optimization process using a second laser (1064 nm nano laser, power of 50 W, scanning speed of 50 M/s, laser spot diameter of 200 μm), a bias voltage of −20V, and a performing temperature of 200° C. to obtain the solar cell of Example 23.

TABLE 3

| | | Sintering | Laser opening | Laser-enhanced contact |
|---|---|---|---|---|
| | Slurry | temperature | process | optimization process |
| Example 1 | Slurry A | 680° C. | X | X |
| Example 2 | Slurry A | 640° C. | X | X |
| Example 3 | Slurry A | 640° C. | X | ◯ |
| Example 4 | Slurry 1 | 200° C. | ◯ | X |
| Example 5 | Slurry 1 | 200° C. | ◯ | ◯ |
| Example 6 | Slurry 1 | 350° C. | ◯ | X |
| Example 7 | Slurry 1 | 350° C. | ◯ | ◯ |
| Example 8 | Slurry 1 | 400° C. | ◯ | X |
| Example 9 | Slurry 1 | 400° C. | ◯ | ◯ |
| Example 10 | Slurry 1 | 450° C. | ◯ | X |
| Example 11 | Slurry 1 | 450° C. | ◯ | ◯ |
| Example 12 | Slurry 1 | 500° C. | ◯ | X |
| Example 13 | Slurry 1 | 500° C. | ◯ | ◯ |
| Example 14 | Slurry 1 | 550° C. | ◯ | X |
| Example 15 | Slurry 1 | 550° C. | ◯ | ◯ |
| Example 16 | Slurry 1 | 600° C. | ◯ | X |
| Example 17 | Slurry 1 | 600° C. | ◯ | ◯ |
| Example 18 | Slurry B | 350° C. | ◯ | X |
| Example 19 | Slurry B | 350° C. | ◯ | ◯ |
| Example 20 | Slurry B | 600° C. | ◯ | X |
| Example 21 | Slurry B | 600° C. | ◯ | ◯ |
| Example 22 | Slurry 1 | 400° C. | X | X |
| Example 23 | Slurry 1 | 400° C. | X | ◯ |
| Example 24 | Slurry 2 | 500° C. | ◯ | X |
| Example 25 | Slurry 2 | 500° C. | ◯ | ◯ |
| Example 26 | Slurry 3 | 500° C. | ◯ | X |
| Example 27 | Slurry 3 | 500° C. | ◯ | ◯ |
| Example 28 | Slurry 4 | 500° C. | ◯ | X |
| Example 29 | Slurry 4 | 500° C. | ◯ | ◯ |
| Example 30 | Slurry 5 | 500° C. | ◯ | X |
| Example 31 | Slurry 5 | 500° C. | ◯ | ◯ |
| Example 32 | Slurry 6 | 500° C. | ◯ | X |
| Example 33 | Slurry 6 | 500° C. | ◯ | ◯ |
| Example 34 | Slurry 7 | 500° C. | ◯ | X |
| Example 35 | Slurry 7 | 500° C. | ◯ | ◯ |

### Solar Cell Performance Evaluation

The contact resistance (Rs), leakage resistance (Rshunt), short-circuit current density (Isc), open-circuit voltage (Voc), fill factor (FF), and cell efficiency (Eff) of the solar cells of Examples 1-35 were measured by a solar simulators according to IEC 60904-9:2020 standard. The results are listed in Table 4.

TABLE 4

| | Voc(V) | Isc(A) | Rs (mohm) | Rshunt (ohm · cm²) | FF(%) | Eff(%) |
|---|---|---|---|---|---|---|
| Example 1 | 0.698 | 10.26 | 5.30 | 960.27 | 79.29 | 22.53 |
| Example 2 | 0.697 | 9.13 | 45.70 | 2360.55 | 37.61 | 9.50 |
| Example 3 | 0.701 | 10.17 | 5.00 | 1244.35 | 81.61 | 23.09 |
| Example 4 | 0.501 | 5.11 | 50.10 | 21.00 | 2.00 | 0.20 |
| Example 5 | 0.505 | 5.12 | 49.20 | 23.00 | 2.50 | 0.25 |
| Example 6 | 0.703 | 10.20 | 9.50 | 1832.11 | 70.42 | 20.04 |
| Example 7 | 0.703 | 10.20 | 5.20 | 1852.62 | 80.33 | 22.85 |
| Example 8 | 0.702 | 10.22 | 8.50 | 1722.32 | 73.55 | 20.92 |
| Example 9 | 0.701 | 10.23 | 4.90 | 1514.22 | 81.68 | 23.05 |
| Example 10 | 0.702 | 10.21 | 8.10 | 1687.24 | 73.22 | 20.82 |
| Example 11 | 0.698 | 10.21 | 5.00 | 1677.78 | 81.43 | 23.02 |
| Example 12 | 0.702 | 10.22 | 8.30 | 1560.81 | 73.47 | 20.90 |
| Example 13 | 0.696 | 10.20 | 4.90 | 1075.75 | 81.66 | 23.01 |
| Example 14 | 0.698 | 10.21 | 7.50 | 1388.96 | 72.11 | 20.82 |
| Example 15 | 0.695 | 10.21 | 6.50 | 1378.33 | 80.71 | 22.73 |
| Example 16 | 0.699 | 10.21 | 8.10 | 2321.22 | 73.22 | 20.87 |
| Example 17 | 0.697 | 10.21 | 5.20 | 1988.21 | 80.51 | 22.89 |
| Example 18 | 0.498 | 4.90 | 60.11 | 10.00 | 1.00 | 0.09 |
| Example 19 | 0.496 | 4.81 | 59.20 | 11.00 | 1.10 | 0.10 |
| Example 20 | 0.498 | 4.90 | 30.47 | 8.00 | 5.00 | 0.48 |
| Example 21 | 0.496 | 4.81 | 28.43 | 7.50 | 5.30 | 0.50 |
| Example 22 | 0.390 | 4.76 | 70.31 | 30.00 | 0.50 | 0.03 |
| Example 23 | 0.395 | 4.78 | 67.88 | 29.00 | 0.40 | 0.03 |
| Example 24 | 0.701 | 10.22 | 9.80 | 1533.87 | 72.03 | 20.48 |
| Example 25 | 0.700 | 10.21 | 5.56 | 1540.44 | 80.47 | 22.83 |
| Example 26 | 0.700 | 10.22 | 8.70 | 2107.20 | 71.62 | 20.86 |
| Example 27 | 0.701 | 10.23 | 5.60 | 2200.30 | 80.33 | 22.86 |
| Example 28 | 0.701 | 10.23 | 9.10 | 1677.87 | 71.05 | 20.22 |
| Example 29 | 0.701 | 10.22 | 8.20 | 1488.21 | 78.81 | 22.40 |
| Example 30 | 0.701 | 10.23 | 9.50 | 1533.43 | 70.33 | 20.01 |
| Example 31 | 0.701 | 10.22 | 5.30 | 1411.77 | 80.89 | 22.99 |
| Example 32 | 0.701 | 10.21 | 9.10 | 1712.88 | 70.11 | 19.91 |
| Example 33 | 0.701 | 10.21 | 5.50 | 1469.77 | 80.77 | 22.94 |
| Example 34 | 0.700 | 10.21 | 9.50 | 1978.22 | 69.88 | 19.82 |
| Example 35 | 0.699 | 10.22 | 5.60 | 1897.63 | 80.56 | 22.84 |

As can be seen from Tables 1 to 4 above, with the same conductive paste, Examples 5, 7, 9, 11, 13, 15, 17, 25, 27, 29, 31, 33, and 35 which have subjected to a laser-enhanced contact optimization process have lower contact resistance than Examples 4, 6, 8, 10, 12, 14, 16, 24, 26, 28, 30, 32, and 34 which have not subjected to a laser-enhanced contact optimization process. Further, under the same process conditions, compared to Examples 19 and 21 which use the conductive pastes that do not contain the glass frit, Examples 7 and 17 which use the conductive pastes containing the glass frit can further reduce the contact resistance by more than 81.7% ((28.4−5.2)/28.4×100%)).

Based on the above conclusions and Tables 1 to 4, it can be clearly seen that compared to the solar cells of Examples 6, 7, 16 and 17 which are prepared using Slurry 1 containing the glass frit, the solar cells of Examples 18 to 21 which are prepared using Slurry B that do not contain the glass frit have higher contact resistance. In the case of using Slurry A containing silver particles, the solar cell of Example 2 which is prepared using a laser opening process have a higher contact resistance than the solar cells of Example 1 which is prepared without a laser opening process. In the cases where the same slurry (Slurry 1) were used, the solar cells of Examples 4 and 5 which are prepared by a sintering temperature of less than 300° C. and the solar cells of Examples 22 and 23 which are prepared without a laser opening process have higher contact resistances than the solar cells of Examples 6 to 17.

Further, as can be seen from the solar cells of Examples 7, 9, 11, 13, 15, 17, 25, 27, 29, 31, 33, and 35, the solar cells prepared using the slurry contains core-shell particles and glass frit, a laser-enhanced contact optimization process and a laser-enhanced contact optimization process have higher fill factor and cell efficiency and lower contact resistance. That is, when the slurry containing core-shell particles and glass frit used together with the laser-enhanced contact optimization process and the laser-enhanced contact optimization process, the electrical characteristics of the solar cells manufactured according to the manufacturing method for the solar cell of the present disclosure can be improved.

In summary, the solar cells manufactured according to the manufacturing method for the solar cell of the present disclosure can have a good contact resistance (Rs) and a low manufacturing cost by using a conductive paste containing glass frit, a laser-enhanced contact optimization process, and a laser-enhanced contact optimization process together.

Although the embodiments and their advantages have been described in detail, it should be understood that various changes, substitutions, and alterations can be made herein without departing from the spirit and scope of the embodiments as defined by the appended claims. Moreover, the scope of the present application is not intended to be limited to the particular embodiments of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein can be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A manufacturing method for a solar cell, comprising:
providing a solar cell semi-finished product, wherein the solar cell semi-finished product comprises:
a silicon substrate;
a first passivation layer disposed on the silicon substrate;
a semiconductor doping layer disposed between the silicon substrate and the first passivation layer; and
an oxide layer disposed between the silicon substrate and the semiconductor doping layer;
performing a laser opening process to form an opening exposing the semiconductor doping layer;
forming a conductive paste in the opening;
performing a firing process; and
performing a laser-enhanced contact optimization process,
wherein the conductive paste comprises:
80 to 120 parts by weight of a plurality of core-shell particles, wherein each of the core-shell particles comprises a core and a shell layer, and the core comprises copper;
0.1 to 14 parts by weight of a glass frit;
5 to 25 parts by weight of an adhesive resin; and
5 to 30 parts by weight of a solvent.

2. The manufacturing method for the solar cell as claimed in claim 1, wherein the sintering process comprises using a sintering temperature of 300° C. to 650° C.

3. The manufacturing method for the solar cell as claimed in claim 2, wherein the sintering process comprises using a sintering temperature of 350° C. to 600° C.

4. The manufacturing method for the solar cell as claimed in claim 1, wherein the laser-enhanced contact optimization process comprises using a laser having a laser wavelength of 400 nm to 1500 nm, a bias voltage of −30V˜30V, and a performing temperature of 20° C. to 300° C.

5. The manufacturing method for the solar cell as claimed in claim 1, wherein the conductive paste comprises 0.2 to 8 parts by weight of the glass frit.

6. The manufacturing method for the solar cell as claimed in claim 1, wherein a weight ratio of the shell layer to the core in each of the core-shell particles is 80:20 to 30:70.

7. The manufacturing method for the solar cell as claimed in claim 1, wherein the shell layer of each of the core-shell particles in the conductive paste is a single layer structure comprising silver, nickel, or an alloy thereof.

8. The manufacturing method for the solar cell as claimed in claim 1, wherein the shell layer of each of the core-shell particles in the conductive paste is a multi-layer structure comprising silver, nickel, or an alloy thereof.

9. The manufacturing method for the solar cell as claimed in claim 1, wherein the solar cell semi-finished product further comprises a second passivation layer disposed between the first passivation layer and the semiconductor doping layer.

10. The manufacturing method for the solar cell as claimed in claim 1, wherein the contact opening process comprises using a picosecond (ps) laser or a femto second (fs) laser having a laser wavelength of 300 nm to 600 nm.

11. The manufacturing method for the solar cell as claimed in claim 1, wherein the step of providing the solar cell semi-finished product comprises providing the silicon substrate, the step of providing the silicon substrate comprises a substrate cleaning process and/or a texture structure forming process.

12. The manufacturing method for the solar cell as claimed in claim 11, wherein the texture structure forming process comprises forming a texture structure comprising a plurality of protrusions and depressions on a surface of the silicon substrate using potassium hydroxide, deionized water, a flocking additive, or any combination thereof.

13. A conductive paste, comprising:
80 to 120 parts by weight of a plurality of core-shell particles, wherein each of the core-shell particles comprises a core and a shell layer, and the core comprises copper;
0.1 to 14 parts by weight of a glass frit;
5 to 25 parts by weight of an adhesive resin; and
5 to 30 parts by weight of a solvent.

14. The conductive paste as claimed in claim 13, wherein the conductive paste comprises 0.2 to 8 parts by weight of the glass frit.

15. The conductive paste as claimed in claim 13, wherein the weight ratio of the shell layer to the core in the core-shell particle is 80:20 to 30:70.

16. The conductive paste as claimed in claim 13, wherein the shell layer of each of the core-shell particles in the conductive paste is a single layer structure comprising silver, nickel, or an alloy thereof.

17. The conductive paste as claimed in claim 13, wherein the shell layer of the core-shell particle in the conductive paste is a multi-layer structure comprising silver, nickel, or an alloy thereof.

18. The conductive paste as claimed in claim 13, wherein the glass frit comprises lead oxide (PbOₓ), silicon oxide (SiO₂), boron trioxide (B₂O₃), aluminum oxide (Al₂O₃), zirconium oxide (ZrO₂), zinc oxide (ZnO), bismuth oxide (Bi₂O₃), strontium oxide (SrO), titanium oxide (TiO₂), platinum oxide (La₂O₃), vanadium oxide (V₂O₅), chalcogenide (GeO₂), or any combination thereof.

19. The conductive paste as claimed in claim 13, wherein the adhesive resin comprises polymer resins, hydroxyethyl celluloses, ethyl celluloses, polyvinyl butyral resins, epoxy resins, acrylic resins, phenolic resins, urea melamine resins, or any combination thereof.

20. The conductive paste as claimed in claim 13, wherein the solvent comprises ester compounds, ether compounds, alcohol compounds, or any combination thereof.
